(19) United States
(12) Patent Application Publication
(10) Pub. No.: US 2024/0162151 A1
(43) Pub. Date: May 16, 2024

(54) BURIED POWER RAIL VIA WITH REDUCED ASPECT RATIO DISCREPANCY

(71) Applicant: International Business Machines Corporation, Armonk, NY (US)

(72) Inventors: Alexander Reznicek, Troy, NY (US); Tsung-Sheng Kang, Ballston Lake, NY (US); Koichi Motoyama, Clifton Park, NY (US); Oscar van der Straten, Guilderland Center, NY (US)

(21) Appl. No.: 18/054,349

(22) Filed: Nov. 10, 2022

(51) Int. Cl. H01L 23/528; H01L 21/8234; H01L 27/088

(52) U.S. Cl. CPC H01L 23/5286; H01L 21/823475; H01L 21/823481; H01L 27/088

(57) ABSTRACT

A semiconductor device includes a shallow trench isolation region extending from a first end surface to a second end surface. The semiconductor device further includes an inner layer dielectric region extending from a third end surface to a fourth end surface. The inner layer dielectric region is arranged such that the fourth end surface is in direct contact with the first end surface. The semiconductor device further includes a transistor arranged in the inner layer dielectric region and a contact via electrically connecting the transistor to a buried power rail. The contact via extends from the second end surface to the third end surface and is narrower at the fourth end surface than at the first end surface.

### BACKGROUND

The present disclosure relates to the semiconductor device fields. In particular, the present disclosure relates to vias that electrically connect transistors with buried power rails and backside power distribution networks.

Semiconductor devices may include buried power rails connected to backside power distribution networks. Vias are interconnect structures used to electrically connect those buried power rails with transistors for the delivery of power and/or signals. Accordingly, such vias can be referred to as buried power rail vias. Current fabrication methods for such vias require forming a very deep trench to enable the resulting via formed in the trench to establish electrical connection between the buried power rail and transistor. Such trenches can be referred to as buried power rail trenches. More specifically, buried power rail trenches must be deep enough such that one end establishes electrical contact with a buried power rail that is in direct contact with a backside power distribution network and the other end establishes electrical contact with a contact pad that is in direct contact with an uppermost surface of a transistor. Additionally, as it extends along this depth, adequate lateral spacing must be maintained between the width of the trench and adjacent transistors to prevent shorting between the resulting via formed in the trench and adjacent structures.

Current fabrication methods used to form such a buried power rail trench necessarily result in the trench having tapered side walls. More specifically, the side walls are angled inwardly from the top of the trench to the bottom of the trench such that the width of the top of the trench is greater than the width of the bottom of the trench. Moreover, the deeper the trench, the larger the difference between the width of the top of the trench and the width of the bottom of the trench.

The width of the bottom of the trench is limited in that it must be sufficiently large to enable the establishment of a reasonable contact area with the buried power rail at the bottom of the trench. However, this minimum width of the bottom of the trench may result in a width of the top of the trench that is too large relative to the spacing between adjacent structures, such as transistors or contact pads. Alternatively, in order to maintain adequate spacing at the top of the trench, the width at the bottom of the trench may be made too small to establish reliable contact area with the buried power rail. Developments in semiconductor fabrication, including trends toward closer spacing of transistors, make it more likely that the width at the bottom of the trench will be too small than that the width at the top of the trench will be made too large.

An additional challenge of using current fabrication methods to form buried power rail trenches is correctly aligning the bottom of the trench and the buried power rail when the bottom of the trench is made very small. Another challenge of using current fabrication methods to form buried power rail trenches is completely filling the bottom of the trench with metal to form the buried power rail via when the bottom of the trench is made very small. Another challenge of using current fabrication methods to form buried power rail trenches is reducing the size of the bottom of the trench, undesirably increases the resistivity of the resulting buried power rail via. Accordingly, current fabrication methods and resulting structures for buried power rail trenches and resulting buried power rail vias suffer from a number of challenges and disadvantages.

### SUMMARY

Embodiments of the present disclosure include a semiconductor device. The semiconductor device includes a shallow trench isolation region extending from a first end surface to a second end surface. The semiconductor device further includes an inner layer dielectric region extending from a third end surface to a fourth end surface. The inner layer dielectric region is arranged such that the fourth end surface is in direct contact with the first end surface. The semiconductor device further includes a transistor arranged in the inner layer dielectric region. The semiconductor device further includes a contact via electrically connecting the transistor to a buried power rail. The contact via extends from the second end surface to the third end surface. The contact via is narrower at the fourth end surface than at the first end surface.

In such embodiments, because the width of the contact via is narrower at the fourth end surface than at the first end surface, where the inner layer dielectric region and the shallow trench isolation region meet, the overall width of the contact via does not exhibit a constant taper from the second end surface to the third end surface. Accordingly, the width of the contact via at the second end surface is not dependent upon the width of the contact via at the third end surface, and vice versa. As a result, the disclosed semiconductor device enables adequate spacing at the top of the contact via and establishment of reliable contact area with the buried power rail at the bottom of the contact via. Additionally, the width of the contact via at the buried power rail can be made large enough to facilitate alignment with the buried power rail during fabrication, to facilitate complete filling of the contact via during metallization, and to reduce an increase in resistivity of the contact via.

Embodiments of the present disclosure may include those in which the shallow trench isolation region includes a first isolation material and a second isolation material that is different than the first isolation material. Such embodiments facilitate the formation of the contact via having a width that is narrower at the fourth end surface than at the first end surface, because the second isolation material can be selectively removed during fabrication, resulting in an opening for a portion of the contact via that has the size and shape of the second isolation material. Accordingly, that portion of the contact via does not exhibit the taper that results from forming the contact via trench using conventional methods and processes.

Additional embodiments of the present disclosure include a semiconductor device. The semiconductor device includes a plurality of transistors arranged in a layer of dielectric material such that a first end surface of each transistor is in direct contact with a layer of silicon. The semiconductor device further includes a shallow trench isolation region formed in the layer of silicon such that the first end surface of each of a first transistor and a second transistor of the plurality of transistors is in direct contact with the shallow trench isolation region. The shallow trench isolation region includes first and second areas of a first isolation material and a third area of a second isolation material that is different than the first isolation material. The first and second areas are separated from one another by the third area.

In such embodiments, the presence of a second isolation material arranged between areas of a first isolation material enables selective removal of the second isolation material to form a void having the dimensions of the area of second isolation material. Such a void can then be used as a portion of a contact via trench such that the resulting contact via will include a portion having the dimensions of the area of second isolation material. Accordingly, in such embodiments, the width of the top of the contact via is not dependent upon the width of the bottom of the contact via, and vice versa. As a result, the disclosed semiconductor device enables adequate spacing at the top of the contact via and establishment of reliable contact area with a buried power rail at the bottom of the contact via. Additionally, the width of the contact via at the buried power rail can be made large enough to facilitate alignment with the buried power rail during fabrication, to facilitate complete filling of the contact via during metallization, and to reduce an increase in resistivity of the contact via.

Additional embodiments of the present disclosure include a method of making a semiconductor device. The method includes forming a plurality of shallow trench isolation regions in a layer of silicon such that each shallow trench isolation region includes first area of a first isolation material and a second area of a second isolation material that is different than the first isolation material and such that each of the first and second areas extends from a first end surface to a second end surface of each shallow trench isolation region. The method further includes forming a layer of dielectric material having a third end surface in direct contact with the first end surface of each shallow trench isolation region and a fourth end surface opposite the third end surface. The method further includes forming a first trench portion through the layer of dielectric material such that the first trench portion is wider at the fourth end surface than at the third end surface and exposes the first end surface of one of the shallow trench isolation regions. The method further includes forming a second trench portion by removing the second area of the one of the shallow trench isolation regions such that the first trench portion and the second trench portion are continuous with one another. The method further includes forming a contact via by filling the first and second trench portions with metal material such that the contact via is wider at the first end surface than at the third end surface.

In such embodiments, forming the first trench portion and the second trench portion separately facilitates the formation of a contact via by filling both the first and second trench portions such that the contact via has a different geometry in the first trench portion than in the second trench portion. Accordingly, such embodiments facilitate the formation of the contact via such that the contact via is wider at the first end surface than at the third end surface, where the layer of dielectric material and the shallow trench regions meet. In other words, such embodiments enable the formation of a contact via that does not exhibit a constant taper from the first end surface to the third end surface. Accordingly, the width of the contact via at the first end surface is not dependent upon the width of the contact via at the third end surface, and vice versa. As a result, the disclosed method enables adequate spacing at the top of the contact via and establishment of reliable contact area with the buried power rail at the bottom of the contact via. Additionally, the disclosed method enables the width of the contact via at the buried power rail to be made large enough to facilitate alignment with the buried power rail during fabrication, to facilitate complete filling of the contact via during metallization, and to reduce an increase in resistivity of the contact via.

The above summary is not intended to describe each illustrated embodiment or every implementation of the present disclosure.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of typical embodiments and do not limit the disclosure.

FIG. 1 illustrates a flowchart of an example method for forming a semiconductor device, in accordance with embodiments of the present disclosure.

FIG. 2 depicts a cross-sectional schematic view of an example of a structure following the performance of a portion of the example method of FIG. 1, in accordance with embodiments of the present disclosure.

FIG. 3 depicts a cross-sectional schematic view of an example of a structure following the performance of a portion of the example method of FIG. 1, in accordance with embodiments of the present disclosure.

FIG. 4 depicts a cross-sectional schematic view of an example of a structure following the performance of a portion of the example method of FIG. 1, in accordance with embodiments of the present disclosure.

FIG. 5 depicts a cross-sectional schematic view of an example of a structure following the performance of a portion of the example method of FIG. 1, in accordance with embodiments of the present disclosure.

FIG. 6 depicts a cross-sectional schematic view of an example of a structure following the performance of a portion of the example method of FIG. 1, in accordance with embodiments of the present disclosure.

FIG. 7 depicts a cross-sectional schematic view of an example of a structure following the performance of a portion of the example method of FIG. 1, in accordance with embodiments of the present disclosure.

FIG. 8 depicts a cross-sectional schematic view of an example of a structure following the performance of a portion of the example method of FIG. 1, in accordance with embodiments of the present disclosure.

FIG. 9 depicts a cross-sectional schematic view of an example of a structure following the performance of a portion of the example method of FIG. 1, in accordance with embodiments of the present disclosure.

FIG. 10 depicts a cross-sectional schematic view of an example of a structure following the performance of a portion of the example method of FIG. 1, in accordance with embodiments of the present disclosure.

FIG. 11 depicts a cross-sectional schematic view of an example of a structure following the performance of a portion of the example method of FIG. 1, in accordance with embodiments of the present disclosure.

FIG. 12 depicts a cross-sectional schematic view of an example of a structure following the performance of a portion of the example method of FIG. 1, in accordance with embodiments of the present disclosure.

FIG. 13 depicts a cross-sectional schematic view of an example of a structure following the performance of a portion of the example method of FIG. 1, in accordance with embodiments of the present disclosure.

FIG. 14 depicts a cross-sectional schematic view of an example of a structure following the performance of a portion of the example method of FIG. 1, in accordance with embodiments of the present disclosure.

FIG. 15 depicts a cross-sectional schematic view of an example of a structure following the performance of a portion of the example method of FIG. 1, in accordance with embodiments of the present disclosure.

FIG. 16 depicts a cross-sectional schematic view of an example of a structure following the performance of a portion of the example method of FIG. 1, in accordance with embodiments of the present disclosure.

FIG. 17 depicts a cross-sectional schematic view of an example of a structure following the performance of a portion of the example method of FIG. 1, in accordance with embodiments of the present disclosure.

FIG. 18 depicts a cross-sectional schematic view of an example of a structure following the performance of a portion of the example method of FIG. 1, in accordance with embodiments of the present disclosure.

FIG. 19 depicts a cross-sectional schematic view of an example of a structure following the performance of a portion of the example method of FIG. 1, in accordance with embodiments of the present disclosure.

FIG. 20 depicts a cross-sectional schematic view of an example of a structure following the performance of a portion of the example method of FIG. 1, in accordance with embodiments of the present disclosure.

### DETAILED DESCRIPTION

The present disclosure relates to the semiconductor device fields. In particular, the present disclosure relates to vias that electrically connect transistors with buried power rails and backside power distribution networks. While the present disclosure is not necessarily limited to such applications, various aspects of the disclosure may be appreciated through a discussion of various examples using this context.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

In general, the various processes used to form a micro-chip that will be packaged into an IC fall into four general categories, namely, film deposition, removal/etching, semiconductor doping and patterning/lithography.

Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film's electrical and mechanical properties.

Removal/etching is any process that removes material from the wafer. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (vacuum) by an electromagnetic field. High-energy ions from the RIE plasma attack the wafer surface and react with it to remove material.

Semiconductor doping is the modification of electrical properties by selectively adding impurities, for example, transistor sources and drains, generally by diffusion and/or by ion implantation. These doping processes may be followed by furnace annealing or by rapid thermal annealing (“RTA”). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and gradually the conductors, insulators and selectively doped regions are built up to form the final device.

Turning now to an overview of technologies that are more specifically relevant to aspects of the present disclosure, as mentioned above, geometrical constraints dictate, to some extent, the sizing and spacing of contact trenches and resulting vias that electrically connect transistors to buried power rails and backside power distribution networks. More specifically, the width of the bottom of the trench must be made sufficiently large to enable the establishment of a reasonable contact area with the buried power rail at the bottom of the trench. However, this minimum width of the bottom of the trench may result in a width of the top of the trench that is too large relative to the spacing between adjacent structures, such as transistors or contact pads. Alternatively, in order to maintain adequate spacing at the top of the trench, the width at the bottom of the trench may be made too small to establish reliable contact area with the buried power rail. Developments in semiconductor fabrication, including trends toward closer spacing of transistors, make it more likely that the width at the bottom of the trench will be too small than that the width at the top of the trench will be made too large.

As described in further detail below, embodiments of the present disclosure provide structures and methods for forming a semiconductor device having a contact trench, and resulting contact via, that electrically connects a transistor to a buried power rail and a backside power distribution network and that does not exhibit a constant taper from its uppermost surface to its lowermost surface. Accordingly, the width at the top of the contact trench, and resulting contact via, are not determined by the width at the bottom of the contact trench, and resulting contact via, and vice versa. Instead, as described in further detail below, the contact trench, and resulting contact via, is formed in two portions, which can have different widths and tapers angles.

As such, embodiments of the present disclosure address the challenge of enabling correct alignment of the bottom of the contact trench and the buried power rail, because the bottom of the trench need not be made as small to accommodate a smaller width at the top of the trench. Furthermore, embodiments of the present disclosure address the challenge of enabling the bottom of the trench to be completely filled with metal to form the buried power rail via, because the bottom of the trench need not be made as small to accommodate a smaller width at the top of the trench. Embodiments of the present disclosure also address the challenge of enabling a reduction in the increase of resistivity of the resulting buried power rail via, because the bottom of the trench need not be made as small to accommodate a smaller width at the top of the trench.

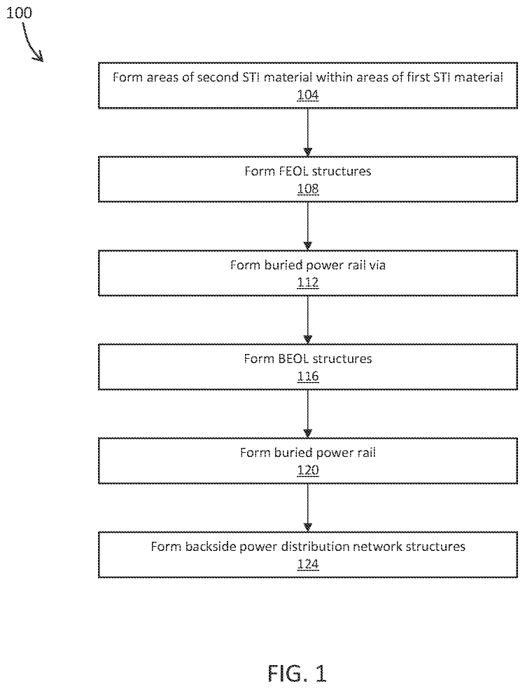

FIG. 1 depicts a flowchart of an example method 100 for forming a semiconductor device, according to embodiments of the present disclosure. The method 100 begins with operation 104, wherein areas of a second shallow trench isolation (STI) material are formed within areas of a first STI material. As described in further detail below, the formation of such areas of STI material can be referred to as performing a shallow trench isolation (STI) process. The technique provides an integrated circuit feature which prevents electric current leakage between adjacent semiconductor device components. In general, STI is performed early during the semiconductor device fabrication process, before transistors are formed. The key steps of the STI process, as described in further detail below, involve etching a pattern of trenches in silicon, depositing one or more dielectric materials (such as silicon dioxide) to fill the trenches, and removing the excess dielectric using a technique such as chemical-mechanical planarization.

Operation 104 of the method 100 further includes removing portions of areas of the first STI material and then filling the spaces formed by the removal of those portions with a second STI material. Accordingly, the performance of operation 104 may be considered a double-STI process, because the STI process is performed twice and results in areas of two different STI materials. In accordance with some embodiments of the present disclosure, the performance of operation 104 further includes the performance of a number of sub-operations.

In accordance with at least one embodiment of the present disclosure, the performance of operation 104 includes forming a pattern of trenches for a first STI material within layers provided on a frontside of a wafer. More specifically, a wafer may be prepared so as to include a layer of substrate material, a layer of sacrificial etch stop material, a layer of silicon, and a nanosheet stack made up of a plurality of alternating sacrificial layers and semiconductor layers. Such a wafer may be prepared such that the layer of sacrificial etch stop material is formed in direct contact with and covering an uppermost surface of the layer of substrate material, such that the layer of silicon is formed in direct contact with and covering an uppermost surface of the layer of sacrificial etch stop material, and such that the nanosheet stack is formed in direct contact with and covering an uppermost surface of the layer of silicon. The preparation of such a wafer is not within the scope of this disclosure and may be performed using known methods and techniques.

In accordance with some embodiments of the present disclosure, the layer of substrate material may be a silicon-containing material. Illustrative examples of silicon-containing materials suitable for the layer of substrate material include, but are not limited to, silicon, silicon germanium, silicon germanium carbide, silicon carbide, polysilicon, epitaxial silicon, amorphous silicon, and multi-layers thereof. Although silicon (Si) is the predominantly used semiconductor material in wafer fabrication, alternative semiconductor materials can be employed, such as, but not limited to, gallium arsenide, gallium nitride, cadmium telluride, zinc selenide, and III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

In accordance with some embodiments of the present disclosure, the layer of sacrificial etch stop material may be formed of an insulative material. For example, the sacrificial etch stop material may be a dielectric layer, such as an oxide, and may be referred to as a buried oxide (BOX) layer. The dielectric layer may be any suitable dielectric, oxide, or the like, and it may electrically isolate further structures from the layer of substrate material.

In accordance with some embodiments of the present disclosure, the nanosheet stack may be formed such that a first sacrificial layer is formed in direct contact with and covering the layer of silicon. A first semiconductor layer is then formed in direct contact with and covering the first sacrificial layer. A number of additional sacrificial layers and semiconductor layers are alternatingly formed on top of one another in this manner. In accordance with at least one embodiment of the present disclosure, four semiconductor layers are formed. However, in alternative embodiments, more or fewer than four semiconductor layers may be formed. In accordance with at least one embodiment of the present disclosure, the uppermost layer of the nanosheet stack is a semiconductor layer. However, in alternative embodiments, a sacrificial layer may form the uppermost layer of the nanosheet stack. In such embodiments, a sacrificial layer may form the lowermost layer and the uppermost layer of the nanosheet stack such that the nanosheet stack includes a greater number of sacrificial layers than semiconductor layers.

In accordance with at least one embodiment of the present disclosure, the sacrificial layers may be composed of, for example, silicon-germanium (e.g., SiGe, wherein the amount of Ge is between approximately 25% and approximately 40%). In accordance with at least one embodiment of the present disclosure, the semiconductor layers may be composed of, for example, silicon.

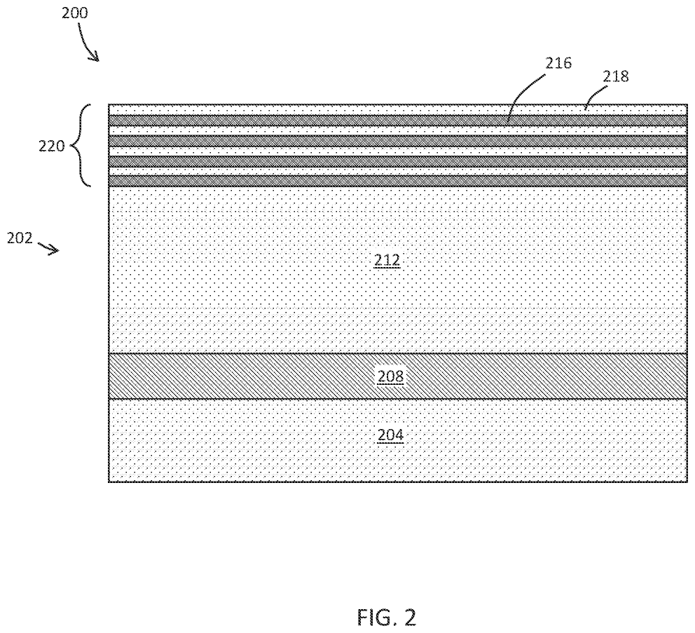

For illustrative purposes, an example of such a wafer 202 is shown in the semiconductor device 200 illustrated in FIG. 2. More specifically, prior to the performance of the method 100, the semiconductor device 200 includes a wafer, such as the wafer 202 illustrated by FIG. 2, that has been prepared so as to include a substrate layer 204, a sacrificial etch stop layer 208, a layer of silicon 212, and a nanosheet stack 220 made up of a plurality of alternating sacrificial layers 216 and semiconductor layers 218.

In accordance with at least one embodiment of the present disclosure, the performance of operation 104 further includes patterning and removing portions of the nanosheet stack and the underlying layer of silicon to form trenches that will subsequently be filled with the first STI material. More specifically, in such embodiments, a hardmask is selectively applied on top of the nanosheet stack in areas where the nanosheet stack is intended to remain. The materials of those areas that are not covered by the hardmask are then removed, such as by etching. More specifically, the layers of the nanosheet stack and a portion of the layer of silicon that are not covered by the hardmask are removed. The removal of these portions of the prepared wafer can be achieved by etching or by another suitable technique.

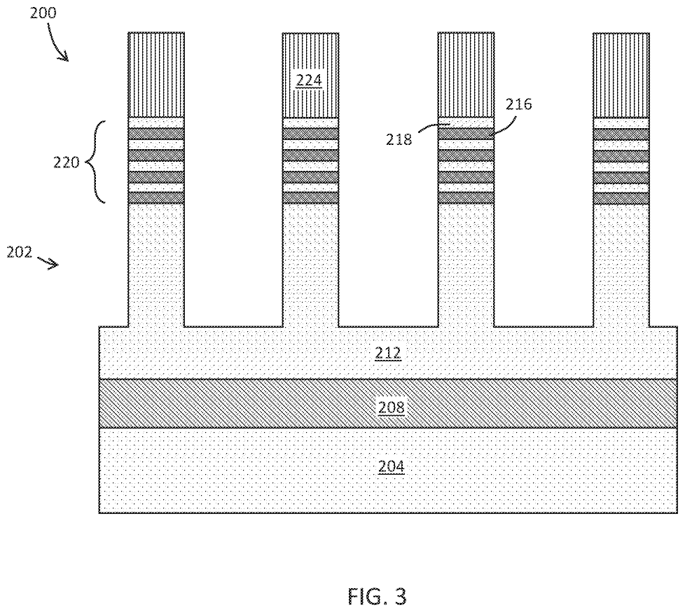

FIG. 3 illustrates the example semiconductor device 200 following the performance of the above portion of operation 104. As shown, a hardmask 224 has been applied to cover portions of the nanosheet stack 220. Materials in the areas that are not covered by the hardmask 224 are then removed. In particular, the nanosheet stack 220 and a portion of the layer of silicon 212 that are not covered by the hardmask 224 are removed to form trenches. In other words, pillars of the layer of silicon 212 and the nanosheet stack 220 are formed underneath each area of hardmask 224. Notably, the removal of material only extends into the layer of silicon 212 of the wafer 202. In other words, the sacrificial etch stop layer 208 and substrate layer 204 are unaffected by the removal of material in the performance of operation 104.

In accordance with at least one embodiment of the present disclosure, the performance of operation 104 further includes filling the trenches that were formed by the removal of the layer of silicon with a first STI material. In accordance with at least one embodiment, the first STI material can be, for example, a silicon dioxide material.

Filling the trenches may include, for example, depositing the first STI material onto the wafer. The trenches are filled such that the first STI material covers all surfaces of the layer of silicon that were exposed by the formation of the openings. In accordance with at least one embodiment, the openings are filled such that an uppermost surface of the first STI material is substantially coplanar with the uppermost surface of the layer of silicon. In other words, the uppermost surface of the first STI material does not cover any surfaces of the lowermost sacrificial layer of the nanosheet stack. In accordance with some embodiments of the present disclosure, planarization may be used to ensure that the uppermost surface of the first STI material is substantially coplanar with the uppermost surface of the layer of silicon and does not cover any surfaces of the lowermost sacrificial layer of the nanosheet stack.

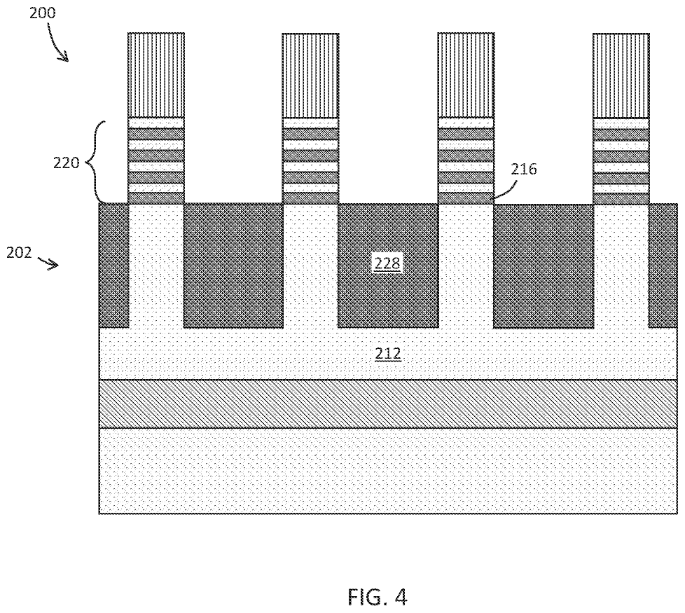

FIG. 4 illustrates the example semiconductor device 200 following the performance of the above portion of operation 104. As shown, a first STI material 228 has been used to fill the trenches. As shown, an uppermost surface of the first STI material 228 is substantially coplanar with an uppermost surface of the layer of silicon 212. More specifically, the uppermost surface of the first STI material 228 is substantially coplanar with the uppermost surface of the layer of silicon 212 where the layer of silicon 212 was covered by the hardmask 224 (as shown in FIG. 3) and was not etched. Accordingly, the uppermost surface of the first STI material 228 does not cover any surfaces of the lowermost sacrificial layer 216 of the nanosheet stack 220. FIG. 4 depicts the wafer 202 following the performance of an STI procedure.

In accordance with at least one embodiment of the present disclosure, the performance of operation 104 further includes forming thick spacers in direct contact with exposed vertical surfaces of the hardmask and remaining portions of the nanosheet stack. Additionally, the thick spacers are formed such that they form a further mask that covers portions of the first STI material within the trenches and covers exposed surfaces of the hardmask and nanosheet stack. In order to act as a mask, the thick spacers are formed of a material that will remain when the first STI material is removed, as described in further detail below.

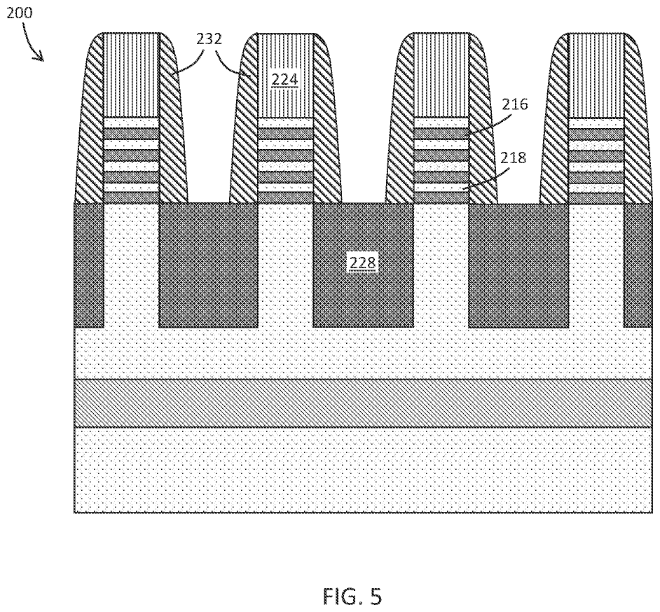

FIG. 5 illustrates the example semiconductor device 200 following the performance of the above portion of operation 104. As shown, thick spacers 232 have been formed in direct contact with exposed vertical surfaces of the hardmask 224 and exposed vertical surfaces of the sacrificial layers 216 and semiconductor layers 218. Accordingly, the thick spacers 232 also cover portions of the uppermost surface of the first STI material 228 that was formed in the trenches. Accordingly, the thick spacers 232 form masks on the uppermost surface of the first STI material 228.

In accordance with at least one embodiment of the present disclosure, the performance of operation 104 further includes the removal of the portions of the first STI material that were not covered, and therefore masked, by the thick spacers. As noted above, to enable the selective removal of the portions of the first STI material, the thick spacers are made of a material that remains when the uncovered portions of the first STI material are removed. The portions of the first STI material are removed down to the layer of silicon. In other words, the removal of the uncovered portions of the first STI material forms further trenches, within the first STI material, that expose the layer of silicon. Accordingly, the further trenches formed by the removal of the uncovered portions of the first STI material have a substantially horizontal bottom surface that is made of the layer of silicon and substantially vertical side surfaces that are made of the first STI material.

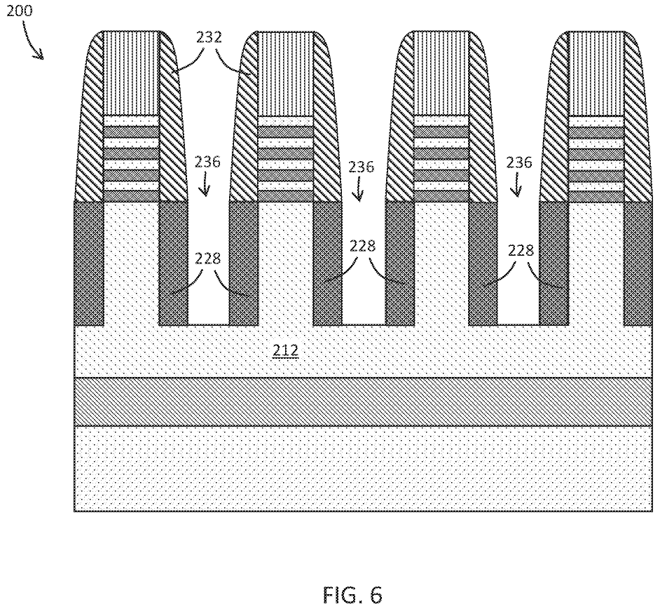

FIG. 6 illustrates the example semiconductor device 200 following the performance of the above portion of operation 104. As shown, further trenches 236 have been formed by the removal of the portions of the first STI material 228 that were not covered by the thick spacers 232. Each of the further trenches 236 extends through the entire thickness of the first STI material 228 such that the layer of silicon 212 is exposed and forms the bottom of each of the further trenches 236. The sides of each of the further trenches 236 are formed by the remaining first STI material 228 that was covered by the thick spacers 232.

In accordance with at least some embodiments of the present disclosure, the performance of operation 104 further includes filling the further trenches with the second STI material in substantially the same manner that the trenches were filled with the first STI material, as described above. Accordingly, the second STI material fills the further trenches such that the second STI material is in direct contact with the layer of silicon and the first STI material and such that the uppermost surface of the second STI material is substantially coplanar with the uppermost surface of the first STI material. Thus, as noted above, the performance of operation 104 can be considered a double-STI process, forming areas of a second STI material within areas of a first STI material.

Notably, the second STI material is a different material than the first STI material. As described in further detail below, the difference in materials enables selective removal of the second STI material without impacting the first STI material that is in direct contact with the second STI material. In other words, the second STI material is a dielectric material (like the first STI material) and is one that can be etched selective to the first STI material.

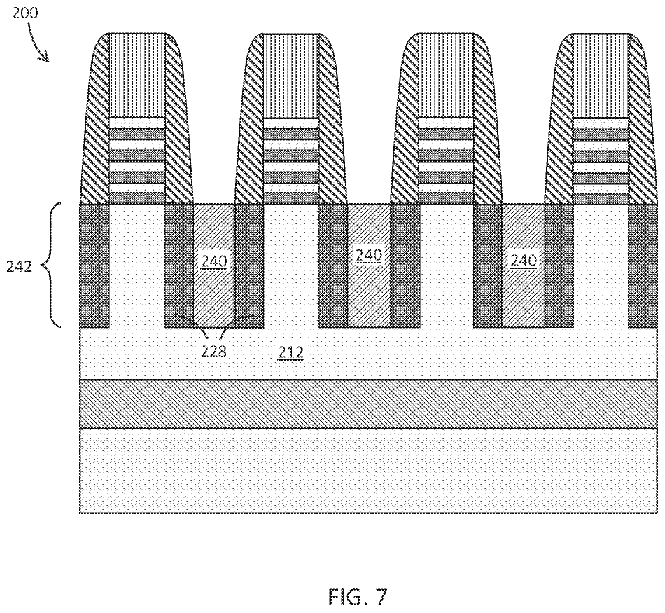

FIG. 7 illustrates the semiconductor device 200 following the performance of the above portion of operation 104. As shown, the further trenches 236 (shown in FIG. 6) have been filled with the second STI material 240 to form areas of the second STI material 240 within areas of the first STI material 228. Because FIG. 7 illustrates the semiconductor device 200 including areas of the second STI material 240 within areas of the first STI material 228, FIG. 7 illustrates the semiconductor device following the performance of operation 104 of the method 100 (shown in FIG. 1).

Following the performance of operation 104, the areas of second STI material 240 formed within areas of first STI material 228 and the interposed areas of the layer of silicon 212 that are substantially coextensive with the areas of first and second STI material 228, 240 can be considered a shallow trench isolation region 242. As noted above, the uppermost surfaces of the first and second STI materials 228, 240 and the layer of silicon 212 are substantially coplanar with one another. Accordingly, this coplanar uppermost surface can be considered the uppermost surface of the shallow trench isolation region 242.

Additionally, the first and second STI materials 228, 240 filled the trenches and further trenches so as to be in direct contact with those portions of the layer of silicon 212 exposed at the bottom of the trenches and further trenches. Accordingly, the lowermost surfaces of the first and second STI materials 228, 240 are in direct contact with the layer of silicon 212 at the bottom of the trenches and are substantially coplanar with one another. Accordingly, this coplanar lowermost surface can be considered the lowermost surface of the shallow trench isolation region 242. Each of the areas of first STI material 228 and each of the areas of second STI material 240 extends from the uppermost surface of the shallow trench isolation region 242 to the lowermost surface of the shallow trench isolation region 242.

Returning to FIG. 1, following the performance of operation 104, the method 100 proceeds with the performance of operation 108, wherein front end of line (FEOL) structures are formed. FEOL structures include integrated circuit components that are patterned on the semiconductor device 200 between the substrate and the metal interconnect layers. In accordance with some embodiments of the present disclosure, the performance of operation 108 further includes the performance of a number of sub-operations.

In accordance with at least one embodiment of the present disclosure, the performance of operation 108 includes removing the thick spacers that were utilized in the performance of 104. The volume that was previously filled with the thick spacers will be subsequently filled with inner layer dielectric (ILD) during the formation of FEOL structures. In an alternative embodiment, the removal of the thick spacers can be considered to be performed during the performance of operation 104 rather than operation 108 as long as the thick spacers are removed prior to the performance of further FEOL processing.

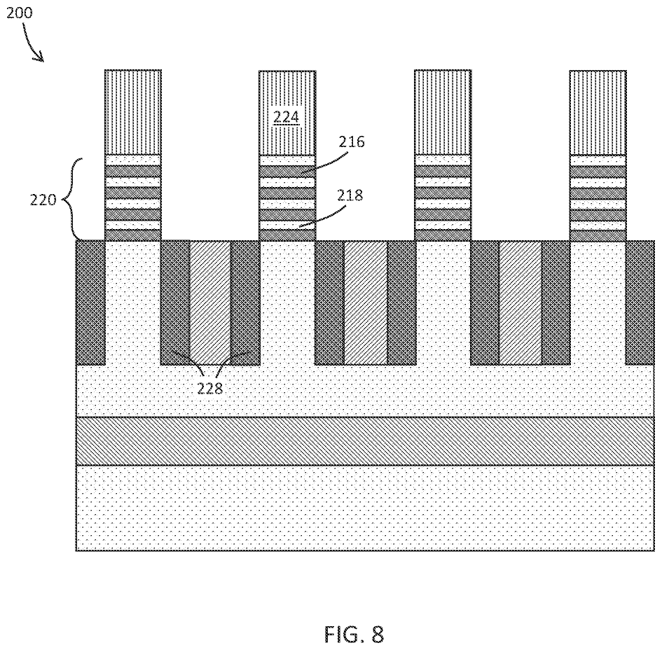

FIG. 8 illustrates the semiconductor device 200 following the performance of the above portion of operation 108. As shown, the thick spacers 232 (shown in FIG. 6) have been removed. Accordingly, vertical surfaces of the sacrificial layers 216 and semiconductor layers 218 of the nanosheet stacks 220 are exposed as well as vertical surfaces of the hardmask 224 and horizontal uppermost surfaces of the first STI material 228.

The performance of operation 108 further includes the performance of standard FEOL processes to form FEOL structures. The processes and formation of such FEOL structures is not within the scope of this disclosure and may be performed using known methods and techniques.

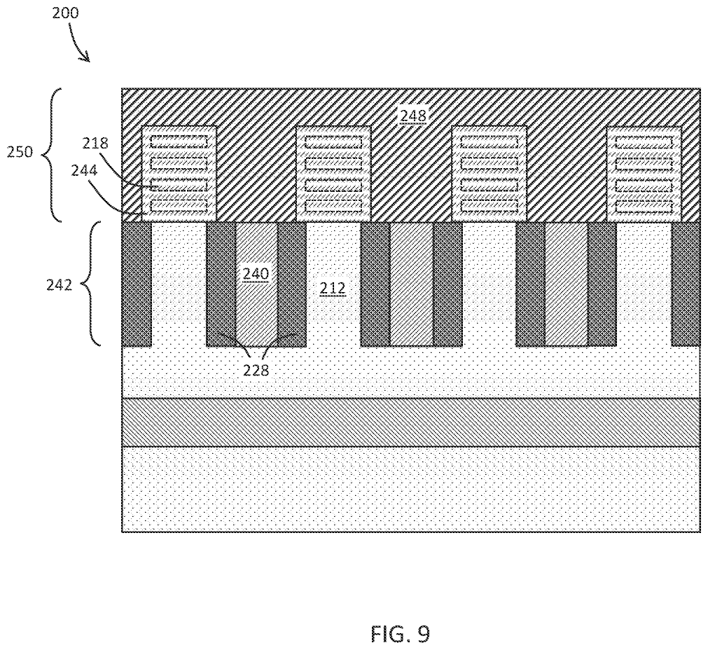

FIG. 9 illustrates the semiconductor device 200 following the performance of operation 108 of the method 100. As shown, the hardmask 224 (shown in FIG. 8) has been removed, the sacrificial layers 216 have been removed, the remaining semiconductor layers 218 of the nanosheet stacks 220 have been surrounded by an epitaxy material 244 to form transistors, and the areas between the epitaxy material 244 of the transistors have been filled with an ILD material 248. Accordingly, the ILD material 248 is in direct contact with the uppermost horizontal surfaces of the first STI material 228 as well as the second STI material 240. In other words, a lowermost surface of the ILD material 248 is in direct contact with the uppermost surface of the shallow trench isolation region 242. Because the epitaxy material 244 provides the outermost surfaces of the transistors, the reference numeral 244 may also or alternatively be used herein to indicate transistors.

Notably, the lowermost surface of the ILD material 248 is substantially coplanar with lowermost surfaces of the epitaxy material 244 of transistors. Additionally, an uppermost surface of the ILD material 248 is arranged above the uppermost surfaces of the epitaxy material 244 of the transistors and is planarized. Accordingly, the region between the lowermost surface of the ILD material 248 and the uppermost surface of the ILD material 248 can be considered an inner layer dielectric region 250, and the inner layer dielectric region 250 can be considered to extend from an uppermost surface, which is coplanar with the uppermost surface of the ILD material 248, to a lowermost surface, which is coplanar with the lowermost surface of the ILD material 248. As shown in FIG. 9, the lowermost surface of the inner layer dielectric region 250 is in direct contact with the uppermost surface of the shallow trench isolation region 242.

Returning to FIG. 1, following the performance of operation 108, the method 100 proceeds with the performance of operation 112, wherein a buried power rail via is formed. As described in further detail below, the formation of the buried power rail via as disclosed herein enables a reduction in the overall aspect ratio of the buried power rail via. As described in further detail below, reduction in the aspect ratio of the buried power rail via reduces shorting, improves metal fill, improves alignment, and improves contact area. In accordance with at least one embodiment of the present disclosure, the performance of operation 112 includes the performance of a number of sub-operations.

In accordance with at least one embodiment of the present disclosure, the performance of operation 112 includes forming a first portion of a via trench in the ILD material such that the first portion of the via trench extends through the entire thickness of the ILD material. The first portion of the via trench exposes a portion of the uppermost surface of an area of the second STI material that is formed beneath the ILD material. The depth of the first portion of the via trench extends from the uppermost surface of the ILD material to the uppermost surface of the area of the second STI material. Accordingly, the depth of the first portion of the via trench is equivalent to the thickness of the ILD material.

The first portion of the via trench is formed between two adjacent transistors such that no portion of any transistor is exposed by the formation of the first portion of the via trench. Accordingly, the width of the first portion of the via trench is limited by the spacing between adjacent transistors.

Due to the standard methods and processes used to form the first portion of the via trench, the resulting shape of the first portion of the via trench is tapered inwardly from the uppermost surface of the ILD material to the uppermost surface of the area of the second STI material. In other words, the first portion of the via trench is wider at its top than at its bottom. The width of the first portion of the via trench relative to its depth is referred to its aspect ratio. Because the width of the first portion of the via trench varies along its depth, the aspect ratio at the top of the first portion of the via trench is different than the aspect ratio at the bottom of the first portion of the via trench. In other words, there is a discrepancy between the aspect ratio at the top of the first portion of the via trench and the aspect ratio at the bottom of the first portion of the via trench.

In general, the width at the bottom of a trench is an important consideration during the formation of trenches in this manner, because the surface area at the bottom of the trench establishes electrical contact. Geometrically, due to the angle of the tapered shape, the deeper the trench is, the wider the width at the top of the trench must be in order to achieve the desired width at the bottom of the trench. However, as mentioned above, the width at the top of the trench is limited by the spacing of the transistors.

In embodiments of the present disclosure, as described in further detail below, because the first portion of the via trench is formed in the ILD material, the depth utilized for this portion of the fabrication process is limited to the thickness of the ILD material. Accordingly, the relative shallowness of the first portion of the via trench in this manner enables a smaller width at the top of the first portion of the via trench, thereby reducing the discrepancy between aspect ratios at the top and bottom of the first portion of the via trench. Benefits of reducing the discrepancy between aspect ratios at the top and bottom of the first portion of the via trench include less shorting between adjacent structures that are subsequently formed on the semiconductor device.

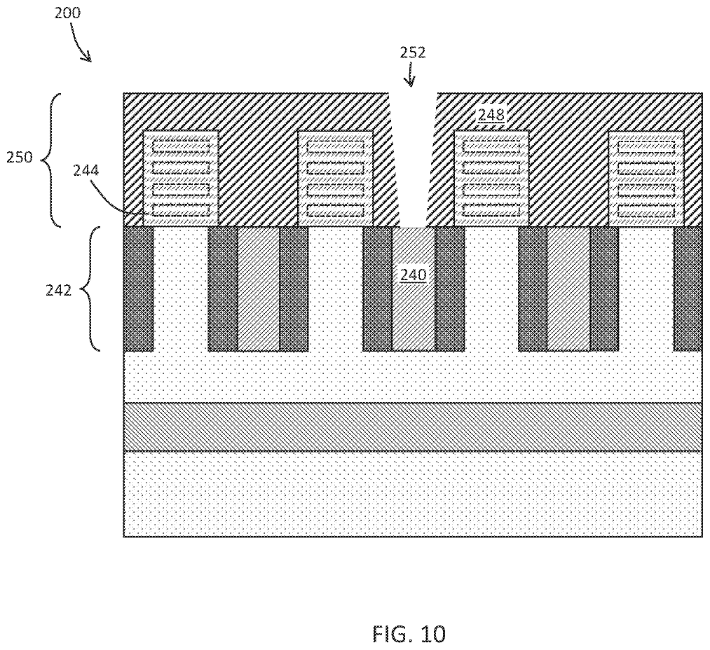

FIG. 10 illustrates the semiconductor device 200 following the performance of the above portion of operation 112. As shown, a first portion of a via trench 252 is formed in the inner layer dielectric region 250 by removing a portion of the ILD material 248 such that the first portion of the via trench 252 is formed between two adjacent transistors (each of which is delimited by respective epitaxy material 244) and such that the uppermost surface of one of the regions of the second STI material 240 is exposed. In other words, the first portion of the via trench 252 extends from the uppermost surface of the ILD material 248, and therefore the uppermost surface of the inner layer dielectric region 250, to the lowermost surface of the ILD material 248, and therefore the lowermost surface of the inner layer dielectric region 250.

In accordance with at least one embodiment of the present disclosure, the performance of operation 112 further includes removing the second STI material that is arranged beneath the first portion of the via trench. More specifically, all of the second STI material in that region is removed such that no second STI material remains between the areas of the first STI material. In other words, the removal of the second STI material forms a second portion of the via trench that is continuous with the first portion of the via trench. Accordingly, the first portion and the second portion of the via trench are combined and make up a complete via trench. The complete via trench extends from the uppermost surface of the ILD material and exposes the surface of the layer of silicon where the second STI material is removed. In accordance with at least one embodiment of the present disclosure, the second STI material can be removed, for example, by performing a local etch that selectively removes the second STI material without impacting the first STI material and layer of silicon in direct contact with that portion of the second STI material.

The dimensions of the second portion of the via trench are equivalent to the dimensions of the second STI material that was removed. Accordingly, the aspect ratio of the second portion of the via trench is substantially consistent from top to bottom, given the substantially rectangular shape of the area of second STI material. Notably, because the second portion of the via trench was formed by selective removal of the second STI material, instead of being formed in the same manner as the first portion of the via trench in the ILD material, the second portion of the via trench does not exhibit the taper that is generated in the formation of the first portion of the via trench. Thus, the discrepancy between the aspect ratios at the top and bottom of the complete via trench is not dependent upon the geometry of the first portion of the via trench. Additionally, the width at the top of the second portion of the via trench is not dependent upon the width at the bottom of the first portion of the via trench. This enables further reduction in the discrepancy between aspect ratios at the top and bottom of the complete via trench.

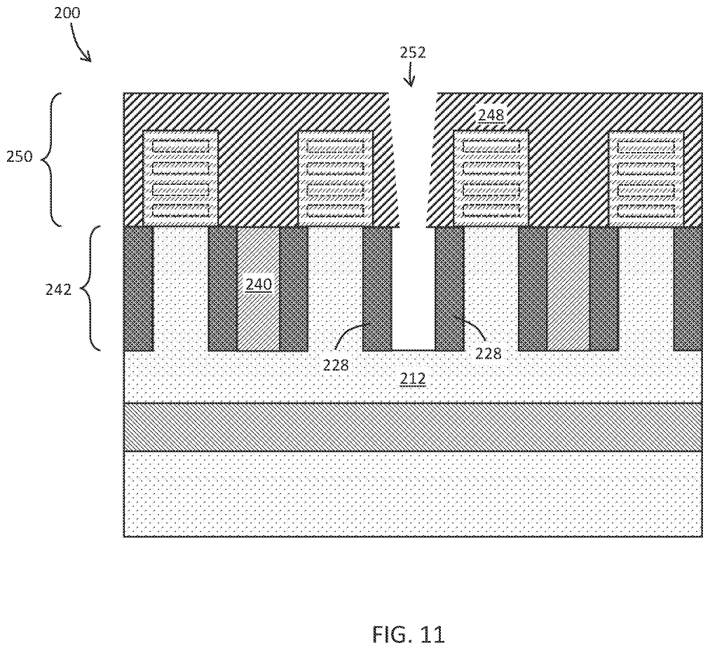

FIG. 11 illustrates the semiconductor device 200 following the performance of the above portion of operation 112. As shown, a second portion of the via trench 252 is formed by removing the second STI material 240 from the region that is contacted by the first portion of the via trench 252. As noted above, all of the second STI material 240 in this area is removed. Accordingly, the resulting complete via trench 252 extends from the uppermost surface of the ILD material 248 to the surface of the layer of silicon 212 that is exposed by the removal of the second STI material 240. In other words, the complete via trench 252 extends from the uppermost surface of the inner layer dielectric region 250 to the lowermost surface of the shallow trench isolation region 242.

The first portion of the via trench 252 is tapered and the second portion of the via trench 252 is not appreciably tapered. As shown, the width at the bottom of the first portion of the via trench 252 is narrower than the width at the top of the second portion of the via trench 252. In other words, the width of the via trench 252 is wider at the uppermost surface of the shallow trench isolation region 242 than it is at the lowermost surface of the inner layer dielectric region 250. Additionally, the width of the via trench 252 is wider at the uppermost surface of the inner layer dielectric region 250 than it is at the lowermost surface of the inner layer dielectric region 250. Additionally, the width of the via trench 252 is not wider at the uppermost surface of the shallow trench isolation region 242 than it is at the lowermost surface of the shallow trench isolation region 242.

Notably, because the width of the second portion of the via trench 252 is substantially the same at its top and bottom, the discrepancy between the aspect ratios at the top and bottom of the complete via trench 252 is less than it would be if the via trench 252 was constantly tapered from the uppermost surface of the inner layer dielectric region 250 to the lowermost surface of the shallow trench isolation region 242. Additionally, because the width at the top of the second portion of the via trench 252 is wider than the width at the bottom of the first portion of the via trench 252, the discrepancy between the aspect ratios at the top and bottom of the complete via trench 252 is less than it would be if the width at the top of the second portion of the via trench 252 was not wider than the width at the bottom of the first portion of the via trench 252.

These relative dimensions of the via trench 252 are equivalent to the relative dimensions of the contact via that is subsequently formed by metallizing the via trench 252. Accordingly, the buried power rail via, described in further detail below, exhibits the relative dimensions described with respect to the via trench 252.

In accordance with at least one embodiment of the present disclosure, the performance of operation 112 further includes patterning middle of line (MOL) contacts on the semiconductor device. The processes of patterning MOL contacts is not within the scope of this disclosure and may be performed using known methods and techniques. Additionally, the particular patterning of MOL contacts is specific to the desired end-use of the semiconductor device. In accordance with at least one embodiment, the performance of this portion of operation 112 can be carried out before, after, or contemporaneously with the previous two portions of operation 112. In other words, embodiments of the present disclosure enable the formation of the complete via trench and the MOL patterning to be completed separately or together and in any order that achieves the desired outcome.

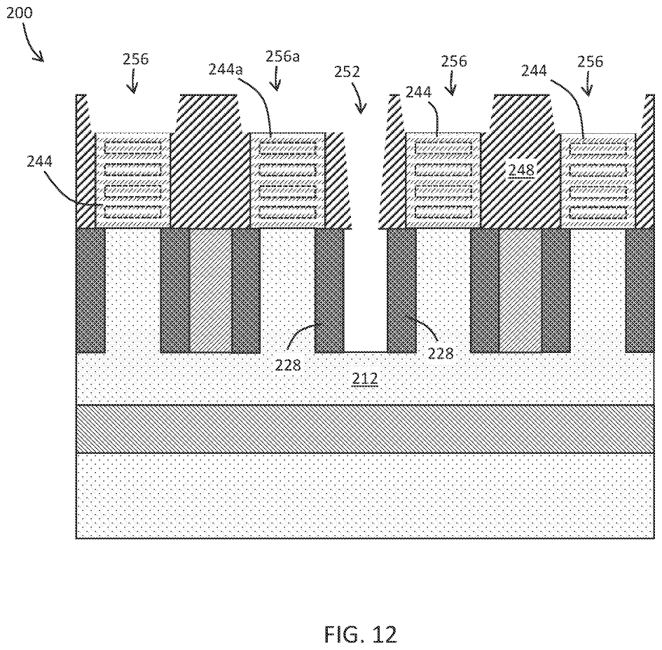

FIG. 12 illustrates the semiconductor device 200 following the performance of the above portion of operation 112. As shown, portions of the ILD material 248 have been selectively removed to form contact areas 256 that expose uppermost surfaces of the epitaxy material 244 of transistors for the subsequent establishment of electrical contact during metallization. One contact area 256a is continuous with the via trench 252 and exposes the uppermost surface of the transistor 244a.

In accordance with at least one embodiment of the present disclosure, the performance of operation 112 further includes metallization. In particular, the contact areas are filled with a metal material to form contact pads, also referred to herein as MOL contacts, and the continuous complete via trench is filled with the metal material to form a contact via, also referred to herein as a buried power rail via. Accordingly, following the performance of this portion of operation 112, the performance of operation 112 is complete.

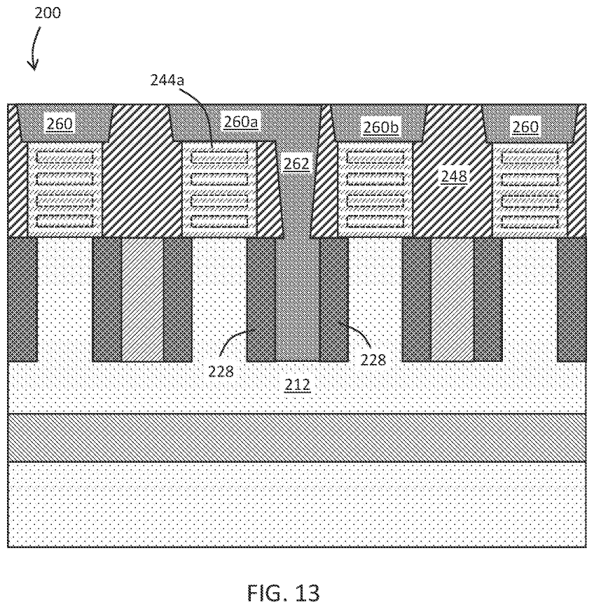

FIG. 13 illustrates the semiconductor device 200 following the performance of operation 112. As shown, the contact areas 256 and the via trench 252 (shown in FIG. 12) have been filled to form MOL contacts 260 and a buried power rail via 262. One of the MOL contacts 260a is continuous with the buried power rail via 262 and is in direct contact with the uppermost surface of the transistor 244a. Notably the MOL contact 260a and buried power rail via 262 are nearest to adjacent MOL contact 260b and are separated from MOL contact 260b by an area of ILD material 248. This separation is made possible by the particular geometry of the buried power rail via 262. More specifically, because the width at the top of the buried power rail via 262 is able to be made smaller due to the formation of the via trench 252 (shown in FIG. 12) as two separate portions having two different geometries, a separation is able to be maintained between the buried power rail via 262 and the adjacent MOL contact 260b.

If the buried power rail via was conventionally formed, and was therefore continuously tapered from top to bottom, generating a similar separation would not be possible without changing the spacing between transistors or making the contact area at the bottom of the buried power rail via problematically small. Accordingly, embodiments of the present disclosure uniquely enable buried power rail vias with reduced discrepancies between aspect ratios at the top and bottom of the buried power rail via that enable reduction in shorts, improved metal fill, improved alignment, and improved contact area relative to conventionally formed buried power rail vias.

Returning to FIG. 1, following the performance of operation 112, the method 100 proceeds with operation 116 wherein back end of line (BEOL) structures are formed. In accordance with at least one embodiment of the present disclosure, the performance of operation 116 can include the performance of a number of sub-operations. The performance of operation 116 includes the performance of standard BEOL processes to form BEOL structures. The processes and formation of such BEOL structures is not within the scope of this disclosure and may be performed using known methods and techniques.

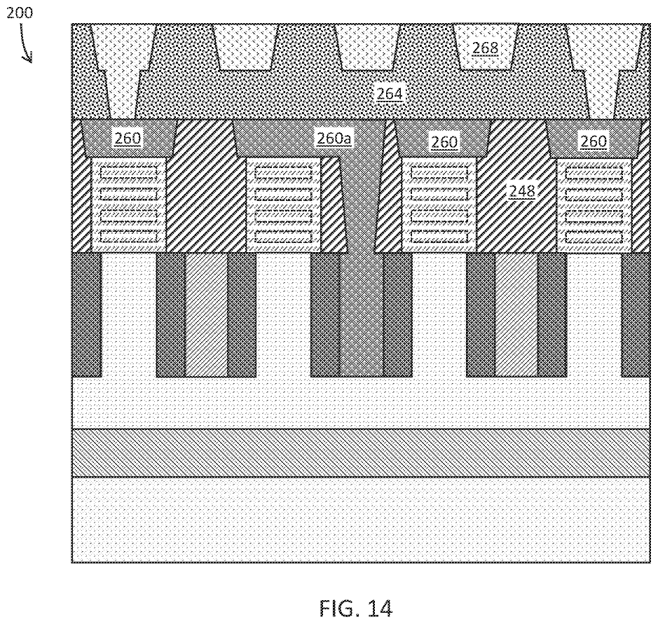

FIG. 14 illustrates the semiconductor device 200 following the performance of a portion of operation 116 of the method 100. As shown, a first layer of BEOL interconnect structures 268 is formed in a surrounding dielectric material 264 above the uppermost surface of the ILD material 248 and MOL contacts 260.

In accordance with at least one embodiment of the present disclosure, the performance of operation 116 further includes forming any number of additional layers of BEOL interconnect structures to establish the desired functionality of the semiconductor device. Additionally, in such embodiments, following the formation of the layers of BEOL interconnect structures, a carrier wafer is bonded to the uppermost layer of BEOL interconnect structures to enable flipping the semiconductor device for further processing.

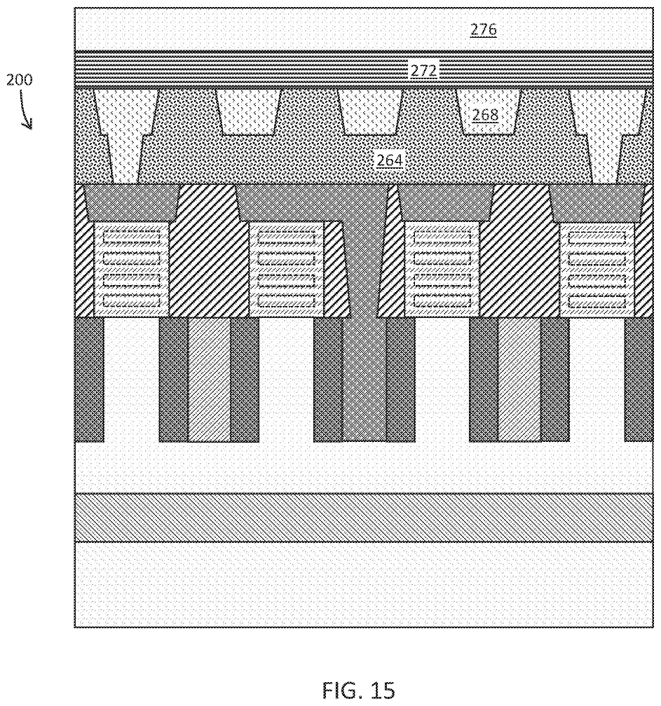

FIG. 15 illustrates the semiconductor device 200 following the performance of operation 116. For simplicity, the additional layers of BEOL interconnect structures are illustratively represented in FIG. 15 by the layer indicated with reference numeral 272. As noted above, the layer 272 can include any number (including zero) of additional layers of BEOL interconnect structures that will be substantially similar to those illustrated by the first layer of BEOL interconnect structures 268 formed in the surrounding dielectric material 264. FIG. 15 further illustrates the carrier wafer 276 bonded to the uppermost layer of BEOL interconnect structures.

Returning to FIG. 1, following the performance of operation 116, the method 100 proceeds with operation 120 wherein a buried power rail is formed. In accordance with at least one embodiment of the present disclosure, the performance of operation 120 can include the performance of a number of sub-operations.

In accordance with at least one embodiment of the present disclosure, the performance of operation 120 includes flipping the semiconductor device as well as removing the substrate layer to facilitate further processing on the back side of the wafer.

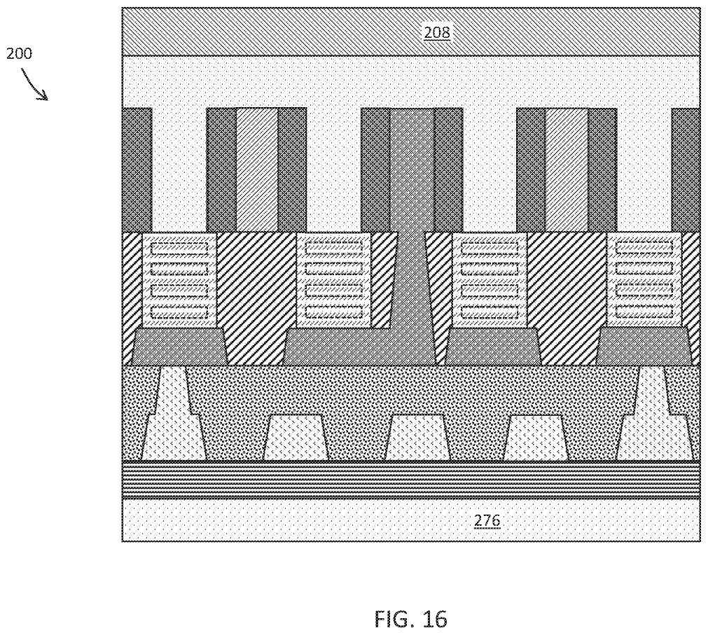

FIG. 16 illustrates the semiconductor device 200 following the performance of this portion of operation 120. Accordingly, as shown, the carrier wafer 276 is arranged at the bottom of FIG. 16 and the substrate layer 204 (shown in FIG. 3) has been removed such that the sacrificial etch stop layer 208 is arranged at the top of FIG. 16.

In accordance with at least one embodiment of the present disclosure, the performance of operation 120 further includes removing the sacrificial etch stop layer from the semiconductor device to facilitate further processing on the back side of the wafer.

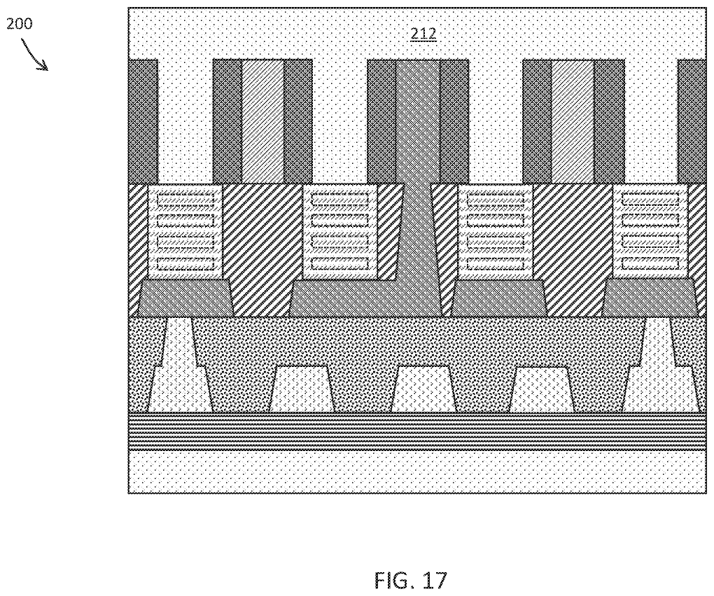

FIG. 17 illustrates the semiconductor device 200 following the performance of this portion of operation 120. As shown, the sacrificial etch stop layer 208 (shown in FIG. 16) has been removed such that the layer of silicon 212 is exposed.

In accordance with at least one embodiment of the present disclosure, the performance of operation 120 further includes removing a portion of the layer of silicon such that an uppermost surface of the buried power rail via is exposed. (Notably, this surface of the buried power rail via could have been previously referred to as a lowermost surface prior to flipping the semiconductor device.) The removal of the portion of the layer of silicon further exposes portions of the first STI material and portions of the second STI material that were previously encapsulated by the layer of silicon.

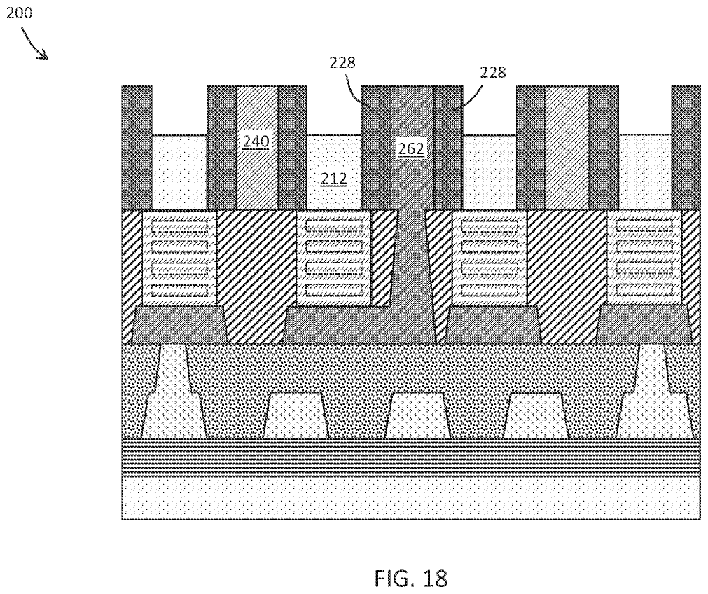

FIG. 18 illustrates the semiconductor device 200 following the performance of this portion of operation 120. As shown, the layer of silicon 212 has been partially removed such that an uppermost surface of the buried power rail via 262 is exposed. Additionally, the removal of the portion of the layer of silicon 212 further exposes portions of the first STI material 228 and portions of the second STI material that were previously encapsulated by the layer of silicon 212. As shown in FIG. 18, the layer of silicon 212 has been recessed relative to the structures encapsulated therein.

In accordance with at least one embodiment of the present disclosure, the performance of operation 120 further includes forming backside interconnect structures, including a buried power rail, on the semiconductor device. In particular, the formation of the backside interconnect structures includes performing a backside ILD fill to fill the voids left by recessing the layer of silicon and to further form a layer of ILD material on top of the first and second STI material and the buried power rail via. In such embodiments, the formation of backside interconnect structures can further include patterning for the backside structures, for example, by selectively masking and removing portions of the ILD material. In such embodiments, the formation of backside interconnect structures can further include metallization to fill the voids in the ILD material that were formed during patterning with metal material. In such embodiments, the buried power rail is formed during this metallization. In other words, part of the metal material that fills the voids in the ILD material forms the buried power rail.

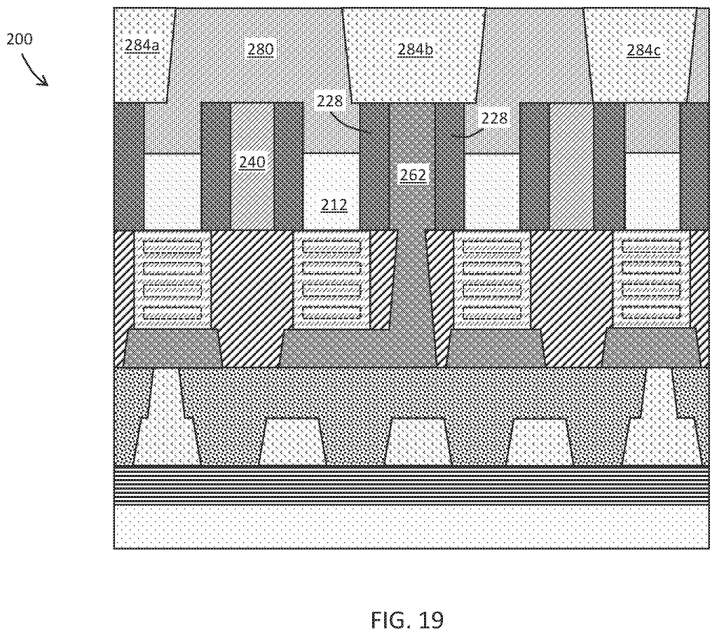

FIG. 19 illustrates the semiconductor device 200 following the performance of operation 120. As shown, an ILD material 280 has been formed to cover exposed surfaces of the layer of silicon 212, the first STI material 228, the second STI material 240, and the buried power rail via 262. Additionally, the ILD material 280 has been patterned and metallized such that metal regions 284a, 284b, and 284c are formed with a metal material. The metal region 284b is a buried power rail and is in direct contact with the buried power rail via 262. Accordingly, the buried power rail via 262 is a via establishing electrical connection with the buried power rail 284b. The buried power rail 284b is also in direct contact with the first STI material 228 on either side of the buried power rail via 262.

Returning to FIG. 1, following the performance of operation 120, the method 100 proceeds with the performance of operation 124 wherein backside power distribution network (BSPDN) structures are formed. The processes and formation of such BSPDN structures is not within the scope of this disclosure and may be performed using known methods and techniques.

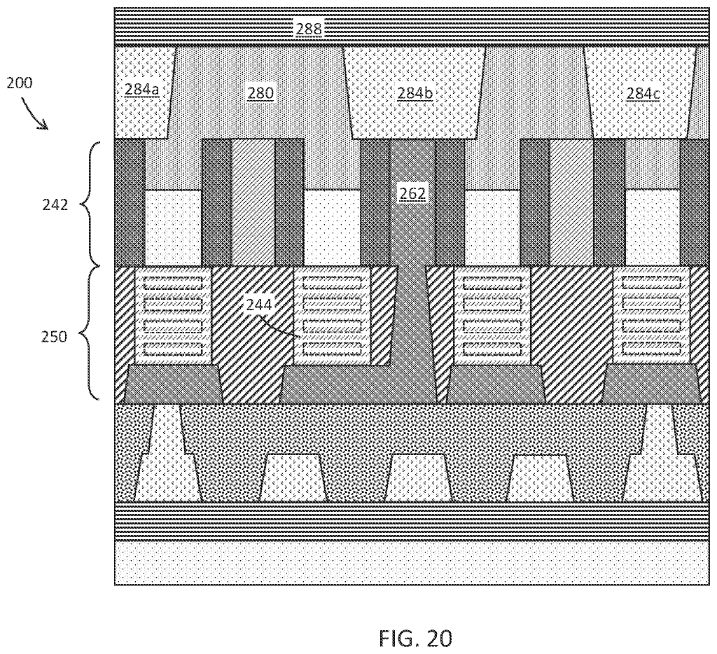

FIG. 20 illustrates the semiconductor device 200 following the performance of operation 124. As shown, BSPDN structures 288 have been formed on the semiconductor device 200 such that the BSPDN structures 288 are in direct contact with the ILD material 280 and with the metal regions 284a, 284b, 284c. For simplicity, the BSPDN structures 288 are illustratively represented in FIG. 20 as a single feature. However, the BSPDN structures 288 may include one or more layers of BSPDN structures built on top of one another depending on the desired functionalities of the semiconductor device 200.

Accordingly, FIG. 20 illustrates the semiconductor device 200 including a shallow trench isolation region 242 extending from an uppermost surface to a lowermost surface thereof and an inner layer dielectric region 250 extending from an uppermost surface to a lowermost surface thereof. (The uppermost and lowermost surfaces being defined prior to flipping the wafer.) The uppermost surface of the shallow trench isolation region 242 is in direct contact with the lowermost surface of the inner layer dielectric region 250. The semiconductor device 200 further includes a transistor 244 arranged in the inner layer dielectric region 250 and a buried power rail via 262 electrically connecting the transistor 244 to a buried power rail 284b. The buried power rail via 262 extends from the uppermost surface of the inner layer dielectric region 250 to the lowermost surface of the shallow trench isolation region 242 and is narrower at the lowermost surface of the inner layer dielectric region 250 than at the uppermost surface of the shallow trench isolation region 242.

In addition to embodiments described above, other embodiments having fewer operational steps, more operational steps, or different operational steps are contemplated. Also, some embodiments may perform some or all of the above operational steps in a different order. Furthermore, multiple operations may occur at the same time or as an internal part of a larger process.

In the foregoing, reference is made to various embodiments. It should be understood, however, that this disclosure is not limited to the specifically described embodiments. Instead, any combination of the described features and elements, whether related to different embodiments or not, is contemplated to implement and practice this disclosure. Many modifications and variations may be apparent to those of ordinary skill in the art without departing from the scope and spirit of the described embodiments. Furthermore, although embodiments of this disclosure may achieve advantages over other possible solutions or over the prior art, whether or not a particular advantage is achieved by a given embodiment is not limiting of this disclosure. Thus, the described aspects, features, embodiments, and advantages are merely illustrative and are not considered elements or limitations of the appended claims except where explicitly recited in a claim(s).

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding the various embodiments. However, the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks.

When different reference numbers comprise a common number followed by differing letters (e.g., 100a, 100b, 100c) or punctuation followed by differing numbers (e.g., 100-1, 100-2, or 100.1, 100.2), use of the reference character only without the letter or following numbers (e.g., 100) may refer to the group of elements as a whole, any subset of the group, or an example specimen of the group.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations.

Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to one skilled in the art. Therefore, it is intended that the following claims be interpreted as covering all such alterations and modifications as fall within the true spirit and scope of the invention.

What is claimed is:

1. A semiconductor device, comprising:
a shallow trench isolation region extending from a first end surface to a second end surface;
an inner layer dielectric region extending from a third end surface to a fourth end surface, the inner layer dielectric region arranged such that the fourth end surface is in direct contact with the first end surface;
a transistor arranged in the inner layer dielectric region; and
a contact via electrically connecting the transistor to a buried power rail, the contact via extending from the second end surface to the third end surface,
wherein the contact via is narrower at the fourth end surface than at the first end surface.

2. The semiconductor device of claim 1, wherein:
the contact via is narrower at the fourth end surface than at the third end surface.

3. The semiconductor device of claim 1, wherein:
the contact via is narrower at the fourth end surface than at the second end surface.

4. The semiconductor device of claim 1, wherein:
the contact via is not narrower at the second end surface than at the first end surface.

5. The semiconductor device of claim 1, wherein:
the shallow trench isolation region and the inner layer dielectric region are arranged on a frontside of an integrated circuit chip; and
the buried power rail and a backside power distribution network are arranged on a backside of an integrated circuit chip.

6. The semiconductor device of claim 5, further comprising:
a contact pad in direct contact with the transistor,
wherein the contact pad is continuously formed with the contact via.

7. The semiconductor device of claim 6, further comprising:
a further transistor arranged in the inner layer dielectric region,
wherein the contact via is arranged between the transistor and the further transistor.

8. The semiconductor device of claim 7, further comprising:
a further contact pad in direct contact with the further transistor,
wherein the further contact pad is spaced apart from the contact via.

9. The semiconductor device of claim 1, wherein:
the shallow trench isolation region includes a first isolation material and a second isolation material that is different than the first isolation material.

10. The semiconductor device of claim 9, wherein:
the second isolation material is in direct contact with the first isolation material from the first end surface to the second end surface.

11. The semiconductor device of claim 9, wherein:
the first isolation material entirely covers side surfaces of the second isolation material from the first end surface to the second end surface.

12. The semiconductor device of claim 9, wherein:
the first isolation material entirely covers side surfaces of the contact via from the first end surface to the second end surface.

13. A semiconductor device, comprising:
a plurality of transistors arranged in a layer of dielectric material such that a first end surface of each transistor is in direct contact with a layer of silicon; and
a shallow trench isolation region formed in the layer of silicon such that the first end surface of each of a first transistor and a second transistor of the plurality of transistors is in direct contact with the shallow trench isolation region, wherein:
the shallow trench isolation region includes first and second areas of a first isolation material and a third area of a second isolation material that is different than the first isolation material, and
the first and second areas are separated from one another by the third area.

14. The semiconductor device of claim 13, further comprising:
a contact via electrically connecting one of the transistors of the plurality of transistors with a buried power rail, the buried power rail in direct contact with a backside power distribution network.

15. The semiconductor device of claim 14, further comprising:
a further shallow trench isolation region formed in the layer of silicon such that the first end surface of each of the second transistor and a third transistor of the plurality of transistors is in direct contact with the further shallow trench isolation region, wherein:
the further shallow trench isolation region includes first and second areas of the first isolation material, and
the first and second areas of the further shallow trench isolation region are separated from one another by the contact via.

16. The semiconductor device of claim 15, wherein:
the further shallow trench isolation region extends from a second end surface to a third end surface, the second end surface in direct contact with the first end surface of the second transistor,
the layer of dielectric material extends from a fourth end surface to a fifth end surface, the fifth end surface in direct contact with the second end surface of the further shallow trench isolation region, and
the contact via extends from the fourth end surface to the third end surface.

17. The semiconductor device of claim 16, wherein:
the contact via is narrower at the fifth end surface than at the second end surface.

18. The semiconductor device of claim 17, wherein:
the contact via is narrower at the fifth end surface than at the fourth end surface.

19. A method of making a semiconductor device, the method comprising:
forming a plurality of shallow trench isolation regions in a layer of silicon such that each shallow trench isolation region includes first area of a first isolation material and a second area of a second isolation material that is different than the first isolation material and such that each of the first and second areas extends from a first end surface to a second end surface of each shallow trench isolation region;
forming a layer of dielectric material having a third end surface in direct contact with the first end surface of each shallow trench isolation region and a fourth end surface opposite the third end surface;
forming a first trench portion through the layer of dielectric material such that the first trench portion is wider at the fourth end surface than at the third end surface and exposes the first end surface of one of the shallow trench isolation regions;
forming a second trench portion by removing the second area of the one of the shallow trench isolation regions such that the first trench portion and the second trench portion are continuous with one another; and
forming a contact via by filling the first and second trench portions with metal material such that the contact via is wider at the first end surface than at the third end surface.

20. The method of claim 19, wherein:
forming the plurality of shallow trench isolation regions includes forming each shallow trench isolation region so as to include a third area of the first isolation material that extends from the first end surface to the second end surface of each shallow trench isolation region and such that the first area and the third area of each shallow trench isolation region are separated by the second area of each shallow trench isolation region.
